(19) United States
(12) Patent Application Publication
(10) Pub. No.: US 2006/0081909 A1
(43) Pub. Date: Apr. 20, 2006

(54) Semiconductor device and manufacturing method therefor

(75) Inventors: Jun Sumino, Tokyo (JP); Satoshi Shimizu, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/245,046

(22) Filed: Oct. 7, 2005

(30) Foreign Application Priority Data
Oct. 12, 2004 (JP) 2004-297652

(51) Int. Cl. H01L 29/788

(52) U.S. Cl. 257/315

(57) ABSTRACT

A semiconductor device comprises a semiconductor substrate, diffusion layer regions formed in the semiconductor substrate, a gate insulating film formed on the semiconductor substrate, gate electrodes formed on the gate insulating film, a silicon nitride film covering the gate electrodes, an interlayer insulating film formed over the semiconductor substrate so as to cover at least a portion of the silicon nitride film on the gate electrodes, and contact plugs formed in the interlayer insulating film and each connected to the diffusion layer region. The contact plugs extend in a width direction of the gate electrodes at predetermined intervals so as to form stripes. These stripes are divided by the gate electrodes.

### BACKGROUND OF THE INVENTION

1. Field of the Invention

The present invention relates to a semiconductor device and a manufacturing method therefor, and more particularly to a highly integrated semiconductor device and a manufacturing method therefor.

2. Background Art

In recent years, as the integration density of semiconductor devices has increased, their internal devices have been miniaturized and hence the dimensions of the semiconductor regions constituting these internal devices have been reduced. As such, there has been a tendency to reduce the size of the contact holes, which are formed in insulating films and filled with wires connected to each semiconductor region, as well as to increase the aspect ratio of these contact holes.

Conventionally, contact holes are formed by anisotropically etching an interlayer insulating film using a photolithographic technique (see, e.g., Japanese Patent Laid-Open Nos. 7-135260 and 2003-78051).

For example, according to the self-aligned contact (hereinafter referred to as “SAC”) technique, first a silicon nitride film is formed over the top surface of each gate electrode, thereby forming silicon nitride film spacers on both side of each electrode. This limits beforehand the regions in which contacts are formed. Then, an interlayer insulating film made up of a silicon oxide film is formed and etched to form contact holes.

However, conventional contact hole forming methods form contact holes such that their sidewalls taper in a vertical direction at a certain taper angle. More specifically, the diameter of each contact hole decreases toward its bottom. As a result, the contact area between each contact plug and the silicon substrate is small. Therefore, when the aspect ratio is high, the etching may stop before completing the formation of contact holes, resulting in an inability to form desired contact holes.

To overcome this problem, the diameter or the taper angle of each contact hole may be increased. However, increasing the diameter might lead to a short between adjacent contacts when the contact holes are laid out with a small pitch. As for increasing the taper angle, it is difficult to form a hole whose sidewall has a taper angle close to 90 degrees. Especially, use of the SAC technique might result in occurrence of a gate-to-contact short around the upper portion of the sidewall of a gate electrode.

### SUMMARY OF THE INVENTION

The present invention has been devised in view of the above problems. It is, therefore, an object of the present invention to provide a semiconductor device having a structure capable of preventing insufficient formation of contact holes, and a manufacturing method therefor.

According to one aspect of the present invention, a semiconductor device comprises a semiconductor substrate, a diffusion layer region formed in the semiconductor substrate, a gate insulating film formed on the semiconductor substrate, a gate electrode formed on the gate insulating film, a first insulating film covering the gate electrode, a second insulating film formed over the semiconductor substrate so as to cover at least a portion of the first gate insulating film on the gate electrode, and contact plugs formed in the second insulating film and connected to the diffusion layer region. The contact plugs extend in a width direction of the gate electrode at predetermined intervals so as to form stripes. The stripes are divided by the gate electrode.

According to another aspect of the present invention, in a method for manufacturing a semiconductor device, a gate insulating film is formed on a semiconductor substrate. A gate electrode is formed on the gate insulating film. A first insulating film is formed to cover the gate electrode. A source diffusion layer region and a drain diffusion region are formed in the semiconductor substrate. A second insulating film is formed over the semiconductor substrate such that the gate electrode having the first insulating film formed thereon is buried under the second insulating film. The second insulating film is etched to form first openings each reaching the source diffusion layer region or the drain diffusion layer region. The first openings extends in a width direction of the gate electrode so as to form stripes which are divided by the gate electrode. The first openings are filled with a conductive material to form contact plugs. The second insulating film and the conductive material are polished by chemical mechanical polishing until the first insulating film is exposed.

Other objects and advantages of the present invention will become apparent from the following description.

### BRIEF DESCRIPTION OF THE DRAWINGS

FIG. 1 is a perspective view of a semiconductor device of the present invention.

FIG. 2 shows a perspective view of a semiconductor device formed using the SAC technique.

FIGS. 3 to 7 show a method for manufacturing a semiconductor device according to the present invention.

### DETAILED DESCRIPTION OF THE PREFERRED EMBODIMENTS

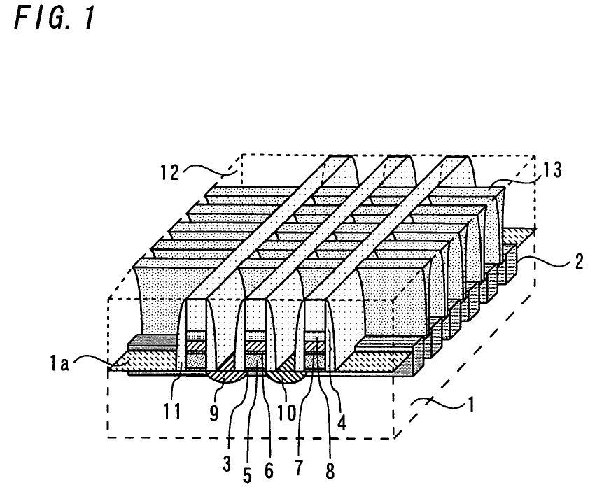

FIG. 1 is a perspective view of a semiconductor device, namely flash memory (exemplary nonvolatile memory), of the present invention. It should be noted that the semiconductor substrate and the interlayer insulating film are only shown in outline to facilitate understanding.

Referring to FIG. 1, device separation regions 2 are formed in a semiconductor substrate 1 (indicated by dashed lines in the figure) so as to extend parallel to one another, forming stripes. Further, a plurality of gate electrodes 4 are formed on a gate insulating film 3 on a principal surface 1a of the semiconductor substrate 1 so as to extend in a direction perpendicular to the device separation regions 2.

Each gate electrode 4 comprises: a floating gate electrode layer 5 made up of a first electrode layer; an interelectrode insulating film 6 formed on the floating gate electrode layer 5; a control gate electrode layer 7 made up of a second electrode layer and formed on the interelectrode insulating film 6; and a metal silicide layer 8 formed on the control gate electrode layer 7.

A source diffusion layer region 9 and a drain diffusion layer region 10 are formed on a respective side of each gate electrode 4. Further, a silicon nitride film 11 (corresponding to a first insulating film) is formed on the sides and tops of the gate electrodes 4.

Further, an interlayer insulating film 12 (corresponding to a second insulating film), indicated by dashed lines in the figure, is formed over the semiconductor substrate 1 so as to cover at least portions of the silicon nitride film 11 on the gate electrodes 4. In the figure, the interlayer insulating film 12 covers the portions of the silicon nitride film 11 other than those on the tops of the gate electrodes 4. Contact plugs 13 each connected to a source diffusion layer region 9 or a drain diffusion layer region 10 are provided within the interlayer insulating film 12.

The present invention is characterized in that: the contact plugs 13 extend in a width direction of the gate electrodes 4 (that is, horizontally in the figure) at predetermined intervals, forming stripes; and these stripes are divided by the gate electrodes 4. With this arrangement, the contact area between each contact plug 13 and the semiconductor substrate 1 can be increased, thereby preventing insufficient formation of contact holes even when the aspect ratio of the pattern (or these contact holes) is high. Furthermore, it is possible to maintain a sufficient gate electrode withstand voltage.

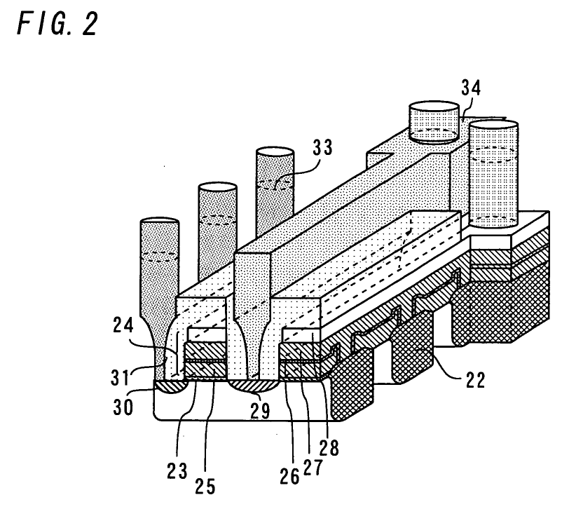

For comparison, FIG. 2 shows a perspective view of a conventional semiconductor device formed using the SAC technique. It should be noted that the semiconductor substrate and the interlayer insulating film have been omitted from the figure to facilitate understanding.

Referring to FIG. 2, a gate insulating film 23 and gate electrodes 24 (corresponding to the gate insulating film 3 and the gate electrodes 4, respectively, in FIG. 1) are formed over a semiconductor substrate (not shown) in which device separation regions 22 are formed. It should be noted that reference numeral 25 denotes a floating gate electrode layer, 26 denotes an interelectrode insulating film, 27 denotes a control gate electrode layer, and 28 denotes a metal silicide layer. Further, a silicon nitride film 31 is formed on the sides and tops of the gate electrodes 24, as in FIG. 1.

Reference numeral 33 denotes drain contact plugs formed in an interlayer insulating film (not shown) and connected to a drain diffusion layer region 30 in the semiconductor substrate. Reference numeral 34, on the other hand, denotes source contact plugs connected to a source diffusion layer region 29 in the semiconductor substrate. The above arrangement results in reduced contact areas between the contact plugs 33 and the diffusion layer region 30 and between the contact plugs 34 and the diffusion layer region 29. Therefore, when the aspect ratio is high, the etching tends to stop before completing the formation of the contact holes.

The present invention, on the other hand, arranges the contact plugs 13 in stripes, each contact plug 13 being connected to a source diffusion layer region 9 or a drain diffusion layer region 10, as shown in FIG. 1. This means that the contact area between each contact plug 13 and the diffusion layer region 9 or 10 is large, as compared to the conventional example shown in FIG. 2, in which the drain contact plugs 33 have a cylindrical shape. This prevents insufficient formation of contact holes during the etching process even when their aspect ratio is high, allowing desired contact holes to be formed.

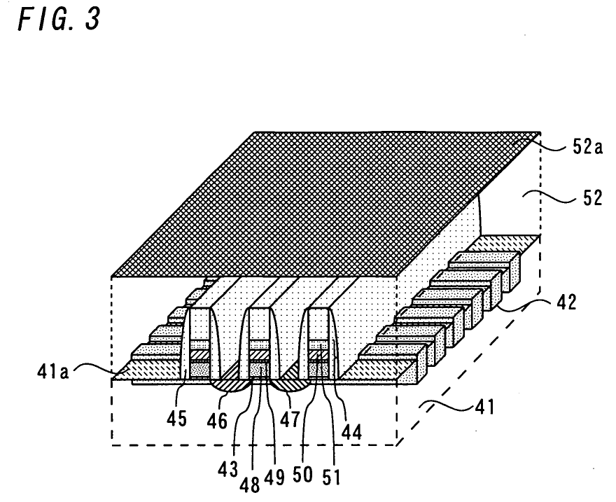

There will now be described a method for manufacturing a semiconductor device according to the present invention with reference to FIGS. 3 to 7. It should be noted that the semiconductor substrate and the interlayer insulating film are only shown in dashed outline to facilitate understanding.

First, after forming device separation regions 42 in a semiconductor substrate 41 (indicated by dashed lines in the figure), a gate insulating film 43, gate electrodes 44, and a silicon nitride film 45 are formed sequentially over a principal surface 41a of the semiconductor substrate 41, as shown in FIG. 3.

For example, a silicon oxide film is buried in predetermined regions of a silicon substrate (the semiconductor substrate 41) to form the device separation regions 42 having an STI (Shallow Trench Isolation) structure. Then, the gate insulating film 43 is formed on the semiconductor substrate 41, and the gate electrodes 44 are formed on the gate insulating film 43. After that, the sides and tops of the gate electrodes 44 are covered with the silicon nitride film 45 for insulation purposes. The portions of the silicon nitride film 45 formed on the sidewalls of the gate electrodes 44 constitute sidewall spacers.

Then, a source diffusion layer region 46 and a drain diffusion layer region 47 are formed on a respective side of each gate electrode 44, as shown in FIG. 3.

According to the present invention, the gate insulating film 43 and the gate electrodes 44 are not limited to any particular material. For example, a silicon oxide film (SiO₂ film) may be used as the gate insulating film 43. Further, the gate electrodes 44 may be formed by laminating a polysilicon film 48 (corresponding to a first electrode layer), a silicon oxide film 49 (corresponding to an interelectrode insulating film), and a polysilicon film 50 (corresponding to a second electrode layer) to one another in that order and then forming a tungsten silicide (WSi) layer 51 (a metal silicide layer) on the polysilicon film 50.

Further, according to the present invention, instead of the silicon nitride film 45, a different type of film may be used to cover the gate electrodes 44. It should be noted, however, that this film must be formed of a material having a high etching selectivity ratio against an interlayer insulating film 52 described later.

Then, the interlayer insulating film 52 (indicated by dashed lines in FIG. 3) is formed over the semiconductor substrate 41 such that the gate electrodes 44 having the silicon nitride film 45 formed thereon are buried under the interlayer insulating film 52. According to the present embodiment, the interlayer insulating film 52 may be a silicon oxide film having a high etching selectivity ratio against the silicon nitride film 45.

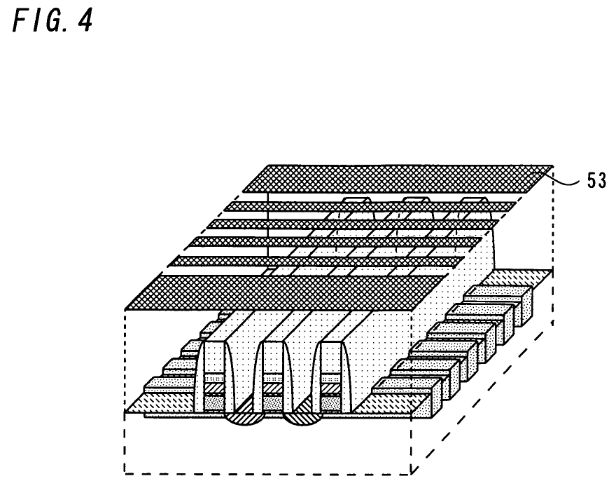

Then, a resist film 53 having a predetermined pattern is formed on a principal surface 52a of the interlayer insulating film 52 by a photolithographic technique, as shown in FIG. 4. The pattern of the resist film 53 has stripes extending in a width direction of the gate electrodes 44 at predetermined intervals. After that, the interlayer insulating film 52 is etched using the resist film 53 as a mask, and then the resist film 53 is removed since it is no longer necessary. The etching of the interlayer insulating film 52 is carried out under such conditions that a high etching selectivity ratio can be achieved against the silicon nitride film 45. With this, first openings (not shown) each reaching a source diffusion layer region 46 or a drain diffusion layer region 47 are formed in the interlayer insulating film 52 without etching the gate electrodes 44.

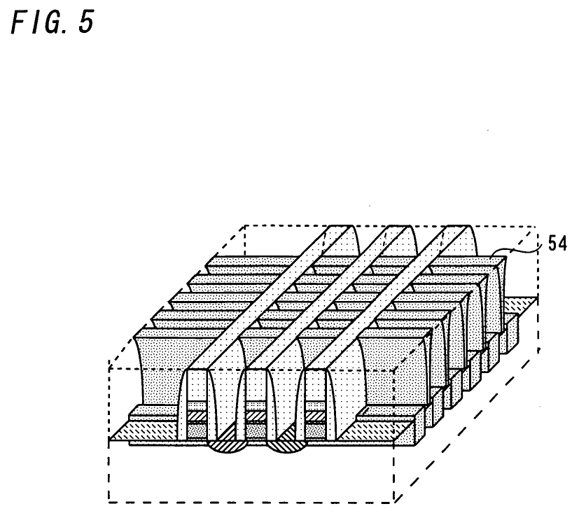

Then, the first openings are filled with a conductive material such as tungsten (W) to form contact plugs 54. Then, the interlayer insulating film 52 is polished by CMP (Chemical Mechanical Polishing) until the surface of the nitride silicon film 45 is exposed, forming the structure shown in FIG. 5.

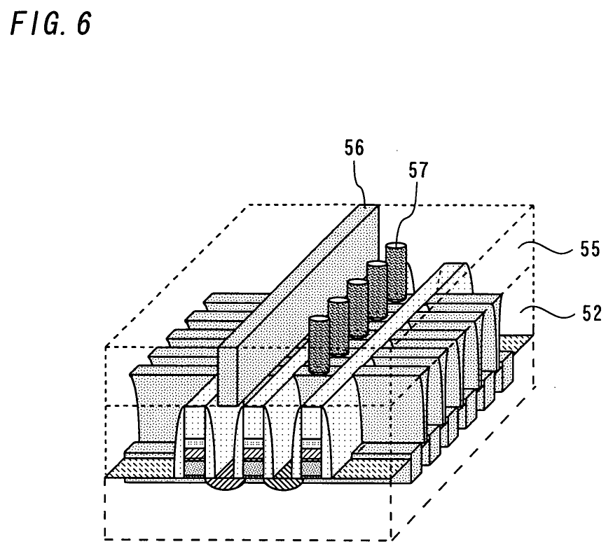

To form electrical nodes connected to the contact plugs 54, an interlayer insulating film 55 (corresponding to a third insulating film), indicated by dashed lines in FIG. 6, is formed on the interlayer insulating film 52 in the structure shown in FIG. 5. Then, second and third openings (not shown) reaching the contact plugs 54 are formed in the interlayer insulating film 55. It should be noted that the second openings reach the contact plugs 54 connected to the source diffusion layer regions 46, while the third openings reach the contact plugs 54 connected to the drain diffusion layer regions 47. Since the interlayer insulating film 55 can be formed to have a smaller thickness than the interlayer insulating film 52, the second and third openings may have a cylindrical shape instead of an extended strip shape. Then, these openings are filled with a conductive material such as tungsten (W) to form source contact plugs 56 and drain contact plugs 57, producing the structure shown in FIG. 6. In FIG. 6, the source contact plugs 56 have an elongated strip shape and the drain contact plugs 57 have a cylindrical shape.

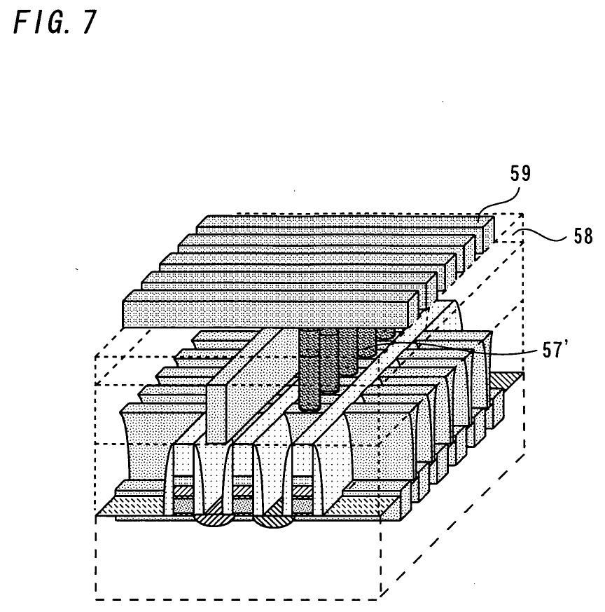

Then, an interlayer insulating film 58 (corresponding to a fourth insulating film), indicated by dashed lines in FIG. 7, is formed on the structure shown in FIG. 6. After that, fourth openings (not shown) reaching the drain contact plugs 57 are formed in the interlayer insulating film 58. The fourth openings have the same shape as the drain contact plugs 57 (that is, a cylindrical shape). Then, the fourth openings are filled with a conductive material such as tungsten (W) to form laminated drain contact plugs 57′. Then, bit lines 59 connected to the drain contact plugs 57′ are formed, producing the structure shown in FIG. 7.

It should be noted that openings reaching the source contact plugs 56 may be formed in the interlayer insulating film 58 and then filled with a conductive material to form laminated source contact plugs. In this case, the openings are formed to have the same shape as the source contact plugs 56, that is, an elongated strip shape.

According to the present embodiment, when openings having a cylindrical shape are formed, their cross section may be elliptical instead of circular. Such an arrangement further prevents insufficient formation of openings.

The features and advantages of the present invention may be summarized as follows.

According to one aspect, a semiconductor device of the present invention is configured such that the contact plugs extend in a width direction of the gate electrode at predetermined intervals so as to form stripes, and these stripes are divided by the gate electrode. This arrangement allows the contact area between each contact plug and the semiconductor substrate to be increased. Therefore, it is possible to prevent insufficient formation of contact holes even when the aspect ratio of the pattern (or these contact holes) is high.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2004-297652, filed on Oct. 12, 2004 including specification, claims, drawings and summary, on which the Convention priority of the present application is based, are incorporated herein by reference in its entirety.

What is claimed is:

1. A semiconductor device comprising:
a semiconductor substrate;
a diffusion layer region formed in said semiconductor substrate;
a gate insulating film formed on said semiconductor substrate;
a gate electrode formed on said gate insulating film;
a first insulating film covering said gate electrode;
a second insulating film formed over said semiconductor substrate so as to cover at least a portion of said first gate insulating film on said gate electrode; and
contact plugs formed in said second insulating film and connected to said diffusion layer region;
wherein said contact plugs extend in a width direction of said gate electrode at predetermined intervals so as to form stripes; and
wherein said stripes are divided by said gate electrode.

2. The semiconductor device according to claim 1, wherein said gate electrode includes:
a floating gate electrode layer made up of a first electrode layer;
an interelectrode insulating film formed on said floating gate electrode layer; and
a control gate electrode layer made up of a second electrode layer and formed on said interelectrode insulating film.

3. The semiconductor device according to claim 1, wherein said first insulating film is a silicon nitride film.

4. The semiconductor device according to claim 1, wherein said second insulating film is a silicon oxide film.

5. A method for manufacturing a semiconductor device, said method comprising the steps of:
forming a gate insulating film on a semiconductor substrate;
forming a gate electrode on said gate insulating film;
forming a first insulating film to cover said gate electrode;
forming a source diffusion layer region and a drain diffusion region in said semiconductor substrate;
forming a second insulating film over said semiconductor substrate such that said gate electrode having said first insulating film formed thereon is buried under said second insulating film;
etching said second insulating film to form first openings each reaching said source diffusion layer region or said drain diffusion layer region, said first openings extending in a width direction of said gate electrode so as to form stripes which are divided by said gate electrode;
filling said first openings with a conductive material to form contact plugs; and
polishing said second insulating film and said conductive material by chemical mechanical polishing until said first insulating film is exposed.

6. The method according to claim 5, further comprising the steps of:
after said polishing step, forming a third insulating film on said first and second insulating films and on said contact plugs;
etching said third insulating film to form second openings and third openings, said second openings reaching the contact plugs connected to said source diffusion layer region, said third openings reaching the contact plugs connected to said drain diffusion layer region;
filling said second and third openings with a conductive material to form source contact plugs and drain contact plugs respectively;
forming a fourth insulating film on said third insulating film;
etching said fourth insulating film to form fourth openings reaching either said source contact plugs or said drain contact plugs;
filling said fourth openings with a conductive material to form contact plugs laminated to either said source contact plugs or said drain contact plugs; and
forming a wiring layer connected to said laminated contact plugs.

7. The method according to claim 6, wherein said second openings have either an elongated strip shape or a cylindrical shape.

8. The method according to claim 6, wherein said third openings have either an elongated strip shape or a cylindrical shape.
